(19) United States
(12) Patent Application Publication
(10) Pub. No.: US 2024/0290787 A1
(43) Pub. Date: Aug. 29, 2024

(54) STRING DRIVER WITH THROUGH SILICON ISOLATION

(71) Applicant: Micron Technology, Inc., Boise, ID (US)

(72) Inventor: Michael A. Smith, Boise, ID (US)

(21) Appl. No.: 18/424,766

(22) Filed: Jan. 27, 2024

Related U.S. Application Data
(60) Provisional application No. 63/448,205, filed on Feb. 24, 2023.

(51) Int. Cl. H01L 27/092; H01L 21/762; H01L 23/00; H01L 23/528; H10B 80/00

(52) U.S. Cl. CPC H01L 27/092; H01L 21/76224; H01L 23/5286; H01L 24/08; H10B 80/00; H01L 2224/08145

(57) ABSTRACT

A string driver device including a substrate; and a plurality of string driver array blocks that are disposed above the substrate, each of the plurality of string driver array blocks including a plurality of active regions that are parallelly aligned along a length direction, a plurality of shared gates that are disposed above the plurality of active regions and along a width direction, the width direction being perpendicular to the length direction, a through silicon isolation (TSI) region that surrounds the plurality of active regions on the substrate and that is disposed between neighboring active regions of the plurality of active regions, and a plurality of shallow trench isolation (STI) regions that are disposed adjacent to one or more channel regions of each of the plurality of active regions and below the plurality of shared gates respectively.

### CROSS-REFERENCE TO RELATED APPLICATION(S)

The present application claims priority to U.S. Provisional Patent Application No. 63/448,205, filed Feb. 24, 2023, the disclosure of which is incorporated herein by reference in its entirety.

### TECHNICAL FIELD

The present disclosure generally relates to string drivers, and more particularly relates to string driver devices with through-silicon isolation (TSI) in wafer-on-wafer (WOW) packaging.

### BACKGROUND

Microelectronic devices fabrication generally includes bonding a wafer, e.g., a complementary metal-oxide-semiconductor (CMOS) wafer to a memory array wafer to form the WOW packages. The CMOS wafer and the memory array wafer can be further mounted on a package substrate or a carrier wafer and encased in a protective covering. The CMOS wafer may include integrated circuitry with a high density of very small components including processor circuits, imager devices, string drivers, and/or high voltage (HV) circuits. On the other hand, the memory array wafer may include memory arrays including NAND flash memory arrays, dynamic random-access memory (DRAM) arrays, and/or phase change memory (PCM) arrays. In the final semiconductor assembly, the memory arrays can be connected, through the string drivers, to the HV circuits of the CMOS device for data signal and control signal transitions. Conventional processes for bonding the CMOS wafer and the memory array wafer include electrically coupling the CMOS wafer string drivers and the memory arrays through through-wafer interconnects (TWI) and forming dielectric-dielectric bonds at the interface of a backside surface of the CMOS wafer and a frontside surface of the memory array wafer, so as to form a pad over CMOS (POC) front-to-back (F2B) WOW packaging.

### BRIEF DESCRIPTION OF THE DRAWINGS

FIG. 1 depicts a schematic view of a WOW bonding scheme including string driver array blocks for semiconductor device assembly according to embodiments of the present technology.

FIG. 2 depicts a top-down view of string driver array blocks with shallow-trench isolation (STI) according to embodiments of the present technology.

FIGS. 3A and 3B depict cross-sectional views of string drivers shown in FIG. 2 according to embodiments of the present technology.

FIG. 4 depicts a top-down view of string driver array blocks with a grounding network according to embodiments of the present technology.

FIGS. 5A and 5B depict cross-sectional views of string drivers shown in FIG. 4 according to embodiments of the present technology.

FIG. 6 depicts a top-down view of string driver array blocks with grounding regions according to embodiments of the present technology.

FIGS. 7A and 7B depict cross-sectional views of string drivers shown in FIG. 6 according to embodiments of the present technology.

FIG. 8 illustrates program voltage traces of string driver devices with grounding regions in an overdrive operation mode according to embodiments of the present technology.

FIG. 9 illustrates program voltage traces of string driver devices with grounding regions in another operation mode according to embodiments of the present technology.

FIG. 10 is a flow chart illustrating a method of processing string driver array blocks with STI according to embodiments of the present technology.

FIG. 11 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

WOW packaging strategies, e.g., the POC F2B WOW bonding, generally separate the production of CMOS devices and memory arrays. For example, CMOS devices can be processed in a CMOS wafer and memory arrays can be processed in a separate memory array wafer, without having any thermal constraints there between. With this configuration, the CMOS devices can be processed in a relative higher temperature compared to the memory array wafer for better device performance. In addition, the CMOS wafer and memory array wafer can be bonded at some step in the fabrication flow after each of their front-end-of-ling (FEOL) processes are completed.

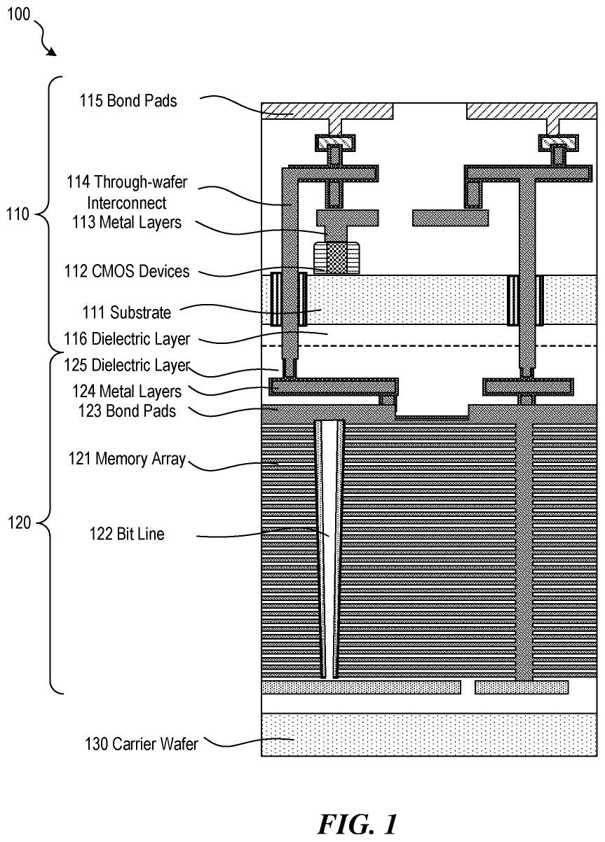

FIG. 1 depicts a schematic view of a POC F2B WOW bonding scheme including string driver array blocks for semiconductor device assembly according to embodiments of the present technology. The POC F2B WOW bonding 100 includes a CMOS wafer 110, a memory array wafer 120, and a carrier wafer 130. As shown, the CMOS wafer 110 is bonded on the memory array wafer 120, which is further mounted on the carrier wafer 120. In this scheme, a backside surface of the CMOS wafer 110 is bonded to a frontside surface of the memory array wafer 120 through a direct bonding technique, e.g., a dielectric-dielectric fusion bonding with strong covalent bonds. The CMOS wafer 110 may include a substrate 111, a plurality of CMOS devices 112 that disposed within or above the substrate 111, a plurality of metal routing layers 113, and a plurality of bond pads 115 disposed on a frontside surface of the CMOS wafer 110. On the other hand, the memory array wafer 120 may include a memory array 121, a plurality of bit lines 122 vertically extending through the memory array 121, and a plurality of bond pads 123 each connected to corresponding one of the plurality of bit lines 122. Notably, the CMOS wafer 110 and the memory array wafer 120 include a dielectric layer 116 and a dielectric layer 125 that are disposed on their backside surface and frontside surface, respectively. Here, the dielectric layers 116 and 125 each provides electric isolation among the components included in each of the CMOS wafer 110 and the memory array wafer 120. Further, the direct bonding interface with fusion bonds between the CMOS wafer 110 and the memory array wafer 120 can be formed by attaching the dielectric layers 116 and 125 and applying heat or compressive pressures there between. In addition, the final metal layers, e.g., the metal layers 113 of the CMOS wafer may have a relatively low processing temperature (e.g., close to 300° C.) and be processed after the WOW direct bonding step.

As shown in FIG. 1, the WOW bonding scheme 100 further includes through-wafer interconnect 114 each connects one metal routing layer 113 to a corresponding one of the plurality of metal layers 124 for HV and control signal transition from the CMOS wafer 110 to the memory array wafer 120. The through-wafer interconnect 114 can be configured to transfer high voltage or data signals to the bit line 122 or word lines (not shown) of the memory array for main operations of read and write of flash pages and erase of memory blocks. Here, the through-wafer interconnect 114 can be fabricated after the completion of CMOS wafer 110 front-end-of-line processes (e.g., before a 1st level of metal process) and the back side thinning of the CMOS wafer 120. Specifically, the through-wafer interconnect 114 can be formed in through holes once the back side surface of the thinned CMOS wafer 110 is bonded to the frontside surface of the memory array wafer 120. In this example, the WOW bonding scheme allows the CMOS wafer 110 and memory array wafer 120 to be built separately. For example, the CMOS wafer 110 and the memory array wafer 120 can be fabricated and optimized separately, before the F2B WOW bonding, at various thermal budget limitations. As a result, the CMOS wafer 110 can be made to be denser and faster to meet increasing data transition requirements.

The WOW packaging strategy typically utilizes a plurality of string drivers that are included in the CMOS devices 112 of the CMOS wafer 110 to transfer control and data signals from a high-voltage (HV) circuit to corresponding word lines of memory arrays 121 of the memory array wafer 120. The string drivers included in the CMOS wafer 110 usually contains HV field-effect-transistors (FETs) that have a relatively large dimension (e.g., large FET device active region dimensions and isolation spaces between adjacent FET devices). Further, the string drivers are generally designed to be pitch devices, meaning they are created in a large block with pitch devices set by an array pitch. It is less flexible to arrange the string driver HV FETs array in the CMOS wafer 110 because the dimensions of the HV FETs array need to satisfy certain limitations. For example, a number of a lengthwise pitch of the string driver FETs array needs to be equal to the number of the string driver array blocks. Moreover, a widthwise pitch of the string driver HV FETs array can be minimized to reduce the die size, but the number of widthwise pitches has to be equal to the number of array tiers.

Traditional methods of increasing string driver device array density includes reductions of widthwise pitch and active area dimension. These methods are getting more and more challengeable as they are limited by the device performance and device-to-device isolation requirements. For example, in a conventional shallow-trench-isolation (STI) scheme in which neighboring string driver HV FETs are isolated by the STI, a narrower action region may result in less transistor drive current due to its geometric width reduction and a degraded body effect caused by interaction of a transistor channel depletion zone with STI trench bottom region. In another example, the reduced active area in string driver HV FETs array may cause reduced breakdown voltage due to reduced space between contacts and an edge of the active area. Further, reducing the space between active areas of string driver device array may result in a leakage between the adjacent string driver HV FETs due to a punch-through effect. This may also cause a decreased breakdown voltage of the string driver device due to reduced space between an implanted region under the STI and the edge of the active area.

To address the above-described challenges and others, the present technology introduces a novel string driver device for the POC F2B WOW packaging scheme. The string driver devices in present technology includes a plurality of shallow trench isolation (STI) regions disposed adjacent to channel regions of parallelly aligned active regions in the string driver array blocks. Moreover, the string driver devices can include a grounding network region connected to the body/well regions of the string driver array blocks, providing a biasing voltage to inhibit the string driver transistor body effects. Alternatively, the string driver devices in the present technology can include a plurality of grounding regions in each of the string driver array blocks. The plurality of grounding regions can be connected to corresponding body/well regions of string driver transistors in the string driver array block, to provide a dedicated biasing voltage control therein. The configurations of string driver devices in the present technology allows an integrations of high voltage (HV) string drivers into the POC F2B WOW bonding scheme while maintaining a high breakdown voltage, good dielectric isolation in the CMOS wafer, and proper body control of the string driver devices.

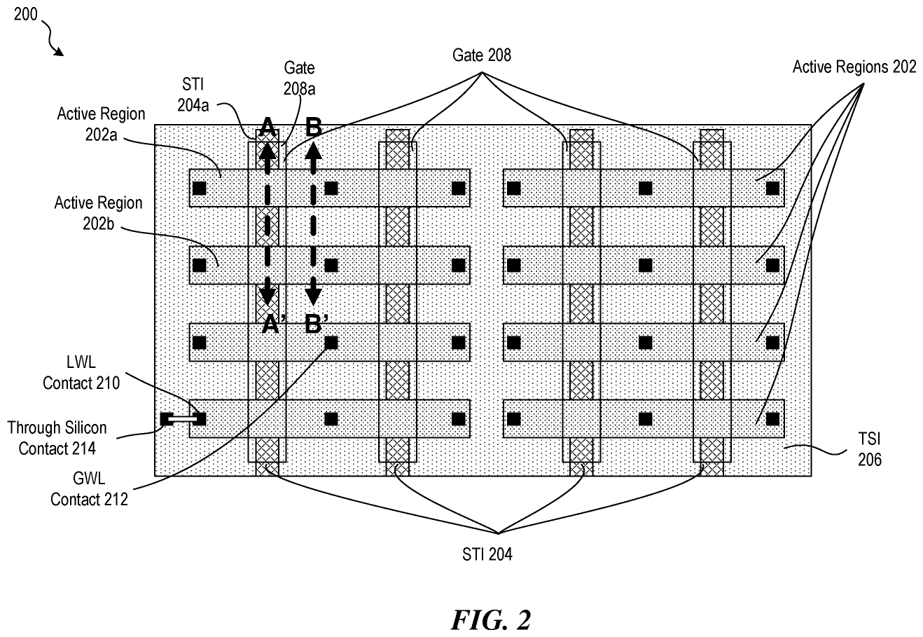

FIG. 2 depicts a top-down view of string driver array blocks 200 with STI according to embodiments of the present technology. As described, the string driver array blocks 200 can be included in the CMOS devices 112 of the CMOS wafer 110 for the F2B POC WOW bonding shown in FIG. 1. In this example, FIG. 2 shows two blocks of string driver device arrays that are aligned horizontally. Specifically, each the string driver device array includes a plurality of active regions 202 that are parallelly aligned and a plurality of shared gates 208 that are disposed above the plurality of active regions 202. The plurality of gates 208 can be made of poly silicon and are in perpendicular to the plurality of active regions 202. Here, each of the plurality of active regions 202 corresponds two transistors have a shard drain region. For example, the active region 202a comprises a source region, a channel region, and a drain region of two transistors with a shared drain region in the middle. Here, the string driver device array can be made of planar MOS transistors with a relatively large dimensions to withstand a high operation voltage, e.g., close to or higher than 30V. In conventional device design and to comply with standard transistor fabrication, the plurality of shared gates 208 is configured to provide a gate voltage to the parallelly aligned string driver transistors in the array block 200. For example, the shared gate 208a is disposed above the parallelly aligned actions regions of the string driver device in the left array block.

In this example, the string driver array blocks 200 includes local word line (LWL) contacts 210 and global word line (GWL) contacts 212 for electrical interconnection between the string driver devices and circuitries outside the sting driver array blocks. Specifically, the LWL contacts 210 can be disposed above the source regions of each of the plurality of active regions 202 and the GWL contacts 212 can be disposed above the shard drain region of each of the plurality of action regions 202. Here, the LWL contacts 210 can be further connected a bonded memory array device through the through-wafer interconnect 114 described in FIG. 1. On another hand, the GWL contacts can be connected to other circuits internal to the CMOS device. In this example, the LWL contacts 210, the GWL contacts 212, and the through silicon contact 214 can be made of conductive materials including at least one of tungsten, molybdenum, nickel, titanium, tantalum, platinum, silver, gold, ruthenium, iridium, rhenium, rhodium, or alloys thereof.

The string driver HV transistor devices, i.e., the plurality of active regions 202 of the string driver array blocks 200, are isolated by the through-silicon insulation (TSI) 206. As shown in FIG. 2, the TSI regions 206 surrounds each of the active regions 202 to provide electrical isolation there between. In this example, the TSI regions 206 may have a depth close to or larger than a well thickness of each of the string driver array blocks, in order to provide an electrical isolation between the wells of the string driver devices. In addition, the string driver array blocks 200 may also include a plurality of through silicon contacts 214 that are disposed in the TSI 206. Here, the through silicon contacts 214 can be disposed close to the two ends of each of the plurality of active regions 202 to be connected with corresponding LWL contact 210 for data/control signal transition.

As shown in FIG. 2, the string driver array blocks 200 include a plurality of STI regions 204 that are disposed below the plurality of gates 208 and perpendicular to the plurality of active regions 202. Specifically, the plurality of STI regions 204 are disposed next to channel regions of each of the plurality of active regions 202. For example, the STI region 204a is continuous between neighboring channel regions of parallelly aligned active regions and along the length direct of the gate 208a. In this example, each of the plurality of STI regions 204 may have a depth less than the TSI 206 so that the neighboring string driver transistors (e.g., the plurality of active regions 202) can share a contiguous well/body area along the width direction of the string driver array blocks. In this example, each of the plurality of STI regions 204 may include a contact (not shown) that transmits a biasing voltage to the body of parallelly aligned neighboring string driver devices to prevent the transistor body effect.

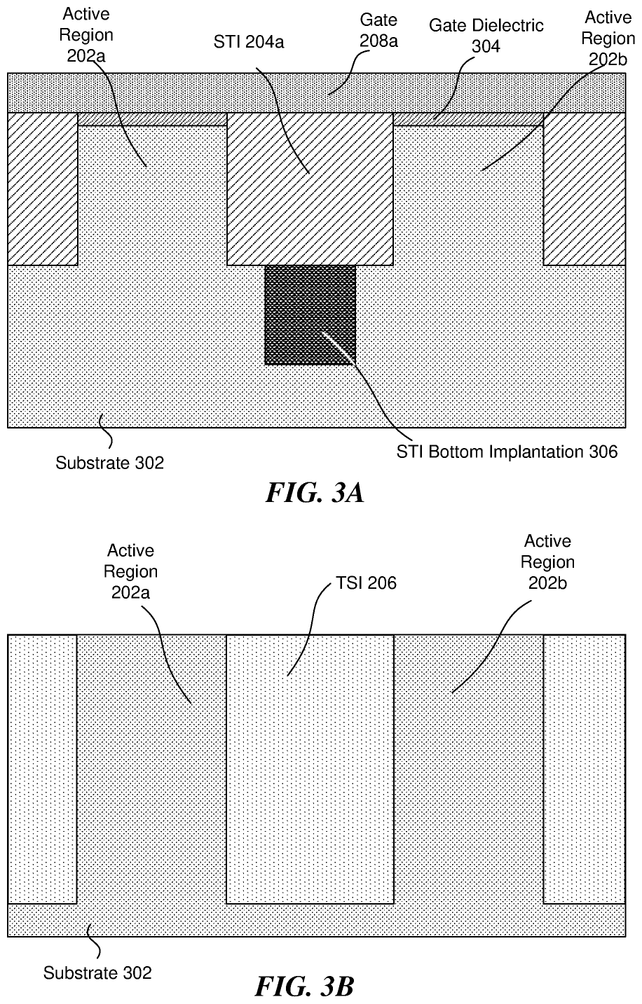

Now turning to FIGS. 3A and 3B which depict cross-sectional views of the string driver device of array blocks 200 along the A-A′ plane and B-B′ plane shown in FIG. 2, respectively. The A-A′ plane is along the length direction of the gate 208a and passes through the gate 208a, the STI 204a, and the active regions 202a and 202b. The B-B′ plane is parallel to the A-A′ plane, passing through the TSI 206, and the active regions 202a and 202b. As shown in FIG. 3A, channels of the active regions 202a and 202b are parallelly aligned on a substrate 302. The gate 208a is disposed above the channels of the active regions 202a and 202b and transfer a shared gate voltage to the corresponding string driver transistors. In this example and for configuration of planar MOSFET string driver device, a gate dielectric layer 304 may be disposed above the top surface of the channel region of the active regions 202a and 202b, and underneath the shared gate 208a. The gate dielectric layer 304 can be made of dielectric material with a high dielectric constant (e.g., SiO₂, ZrO₂, and/or HfO₂). In addition, the channels of neighboring string driver devices, i.e., the channels of the active regions 202a and 202b, are isolated by the STI 204a. The STI 204a can be filled by electrically non-conductive materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Here, a STI bottom implantation region 306 may be implemented under the STI region 204a and between the neighboring aligned active regions 202a and 202b. For a P type lighted doped substrate 302, the STI bottom implantation region 306 may be formed by implanting P type dopant materials such as Boron and/or Gallium therein. In this example, the STI bottom implantation region 306 may be connected to the corresponding contact of the STI 204a, providing a low resistance path to transfer the biasing voltage to the body of parallel aligned neighboring string driver devices. In this example, the STI 204a may have a width close to 0.5 μm and a depth close to a source/drain region depth of corresponding string driver device (e.g., from 0.5 μm to 1 μm). Moreover, each of the active regions 202a and 202b may have a width close to 0.5 μm.

FIG. 3B shows a cross-section view of the string driver device along the B-B′ plane, which passes the drain regions of parallel aligned string driver FET transistors. As shown, the neighboring active regions 202a and 202b are isolated by TSI 206. Specifically, the drain regions of the neighboring aligned string driver device are isolated by the TSI 206 which can be filled by electrically non-conductive materials such as SiO₂. In this example, the TSI 206 has a similar width to the STI 204a, e.g., close to 0.5 μm. Further, the depth of the TSI 206 is deeper than the STI regions 204 across the string driver array blocks 200. For example, the TSI 206 may have a depth ranging from 2 μm to 5 μm, close or large than a well depth of the HV string driver transistor devices. Here, the TSI 206 is configured to provide an electrical isolation between adjacent wells of string driver device.

In this example, the STI 204a and TSI 206 can be processed in parallel during the FEOL processes of the string driver array blocks 200. For example, trenches corresponding to the STI 204a and the TSI 206 can be formed sequentially on the substrate 302 by a proper etching process and using different lithography hard masks. Once the trenches as formed, dielectric materials can be filled therein to form the corresponding electrical isolations. Apparently, as shown in FIGS. 3A and 3B and described above, the trench for STI 204a is shallower than the trench for TSI 206.

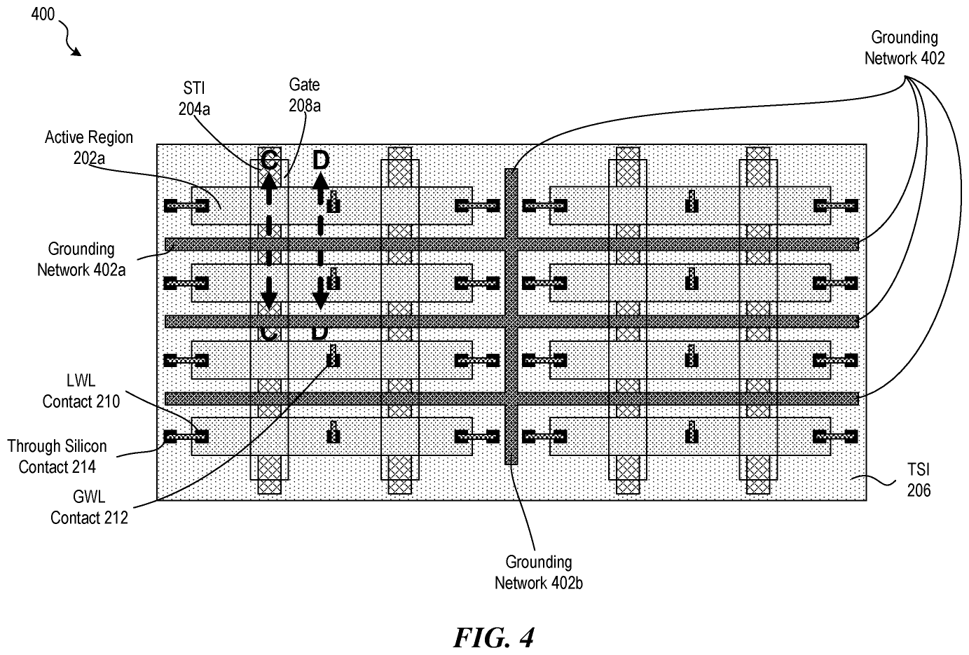

FIG. 4 depicts a top-down view of another string driver array blocks 400 according to embodiments of the present technology. As shown, the string driver array blocks 400 can be fabricated based on the string driver array blocks 200 described in FIG. 2. In addition, the string driver array blocks 400 further include a grounding network 402 which is configured to assist the grounding of the string driver devices included in the array blocks.

In this example, the grounding network 402 is disposed across the neighboring string driver array blocks and between parallelly aligned active regions of corresponding string driver devices. For example, the grounding network 402 includes a plurality of horizontal stripes 402a that are aligned along the length direction of the plurality of active regions 202 and across the string driver array blocks shown on the left and right of FIG. 4. In addition, the grounding network 402 can also include a plurality of vertical stripes 402b that each aligned along the width direction of the string driver array block, being disposed between neighboring string driver array blocks as shown in FIG. 4. Specifically, the horizontal stripes 402a and the vertical stripes 402b of the grounding network 402 can be located within the TSI 206. Moreover, between the channels of neighboring parallelly aligned string driver devices, the horizontal stripes 402a of the grounding network 402 can be partially embedded in the plurality of STI regions 204, respectively.

As shown in FIG. 4, the plurality of horizontal stripes 402a is interconnected with the plurality of vertical stripes 402b to form the grounding network 402 that crosses through the string driver array blocks. Further, the grounding network 402 may include a contact (not shown) that is configured to transfer a biasing voltage to the body of string driver transistors included in the string driver array blocks in order to prevent the transistor body effect. In addition, the horizontal stripes 402a and vertical stripes 402b of the grounding network 402 may be made of heavy doped semiconductor materials. For example, the grounding network 402 can be silicon doped by P type dopant materials such as Boron and/or Gallium in a dose level close to or higher than 1×10²⁰ ions·cm⁻².

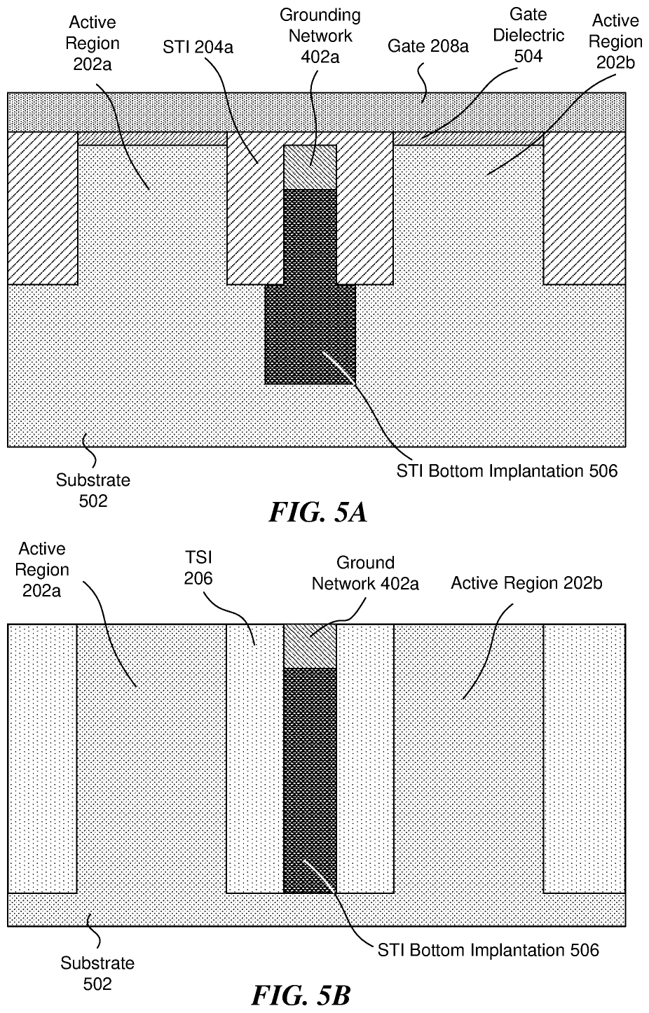

The relative locations and profiles of the grounding network 402 in the string driver array blocks 400 can be further described from cross-section views, as shown in FIGS. 5A and 5B. In particular, FIGS. 5A and 5B illustrate cross-sectional views of string driver devices along the C-C′ plane and the D-D′ plane of FIG. 4, respectively. The C-C′ plane is along the length direction of the gate 208a and passes through the gate 208a, the STI 204a, the active regions 202a and 202b, and the grounding network horizontal stripe 402a. The D-D′ plane is parallel to the C-C′ plane, passing through the TSI 206, the active regions 202a and 202b, and the grounding network horizontal stripe 402a. As shown in FIG. 5A, the channels of the active regions 202a and 202b are parallelly aligned on a substrate 502. The gate 208a is disposed above the channels of the active regions 202a and 202b and transfer a shared gate voltage to the corresponding string driver transistors. In this example and for configuration of planar MOSFET string driver device, a gate dielectric layer 504 may be disposed above the top surface of the channel region of the active regions 202a and 202b, and underneath the shared gate 208a. The gate dielectric layer 504 can be made of dielectric material with a high dielectric constant (e.g., SiO₂, ZrO₂, and/or HfO₂).

In this example, the channels of neighboring string driver devices, i.e., the channels of the active regions 202a and 202b, are isolated by the STI 204a. Here, the grounding network horizontal stripe 402a is embedded in the STI 204a and disposed above a protruded STI bottom implantation region 506. As shown in FIG. 5A, a top surface and sidewall surfaces of the horizontal stripe 402a are in contact to the STI 204a. In addition, the grounding network horizontal stripe 402a is connected, through the STI bottom implantation region 306, to the body of adjacent string driver transistors. The configuration enables a low resistance path for transferring the biasing voltage to the body of parallel aligned neighboring string driver devices to prevent transistor body effect. In this example, the top surface of the grounding network horizontal stripe 402a is not connected to the gate 208a, having a gap filled by STI 204a therebetween to provide an electrical isolation. The grounding network 402 including its horizontal stripes and vertical stripes can be made of silicon and heavily doped by P type dopant materials such as Boron and/or Gallium, in a P type lightly doped substrate 502. Moreover, the STI bottom implantation region 506 can be further extended into the substrate 502 and under the STI 204a, through a proper ion implantation process of implanting P type dopant materials such as Boron and/or Gallium. In this example, the grounding network horizontal strip 402a may be in a square shape from the cross-sectional view. It may have a width close to 0.15 μm and a depth ranging from 0.1 μm to 0.5 μm. Moreover, a distance from the grounding network horizontal strip 402a sidewall to sidewall of adjacent active region 202 can be close to 0.175 μm.

FIG. 5B shows a cross-section view of the string driver device along the D-D′ plane, which passes the drain regions of parallel aligned string driver FET transistors. As shown, the neighboring active regions 202a and 202b are isolated by TSI 206. Specifically, the grounding network horizontal strip 402a is embedded in the TSI 206, having its sidewalls in direct contact to TSI 206. Additionally, the grounding network horizontal strip 402a can be disposed above the STI bottom implantation region 506. In some other examples, the grounding network horizontal stripe 402a can be disposed above a protruded silicon which does not include any additional dopants.

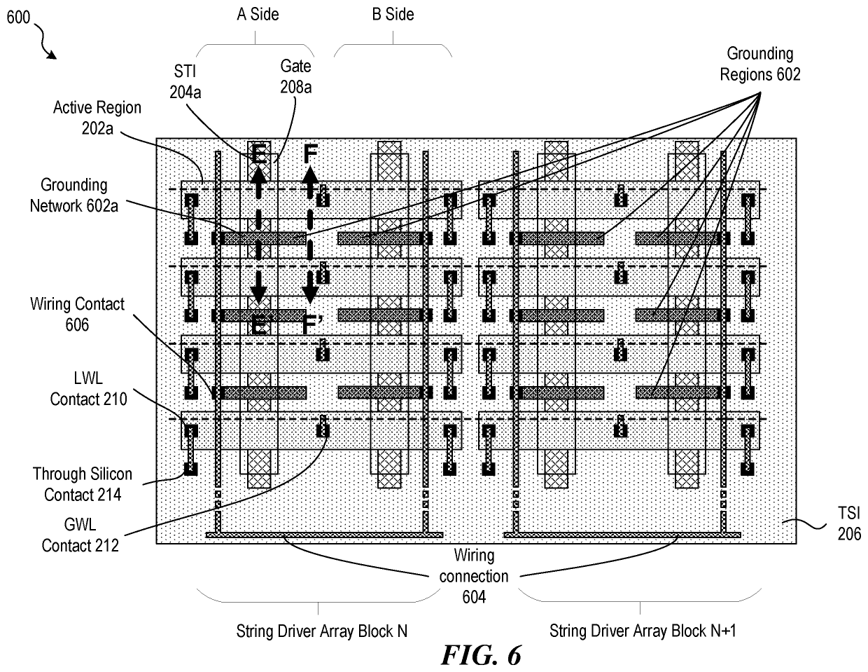

Now turning to FIG. 6 which depicts a top-down view of another string driver array blocks 600 according to embodiments of the present technology. Specifically, the string driver array blocks 600 can be fabricated based on the string driver array blocks 200 described in FIG. 2. In addition, the string driver array blocks 600 further include a plurality of grounding regions 602 that are configured to assist the grounding of the string driver devices included therein. As shown, FIG. 6 illustrates the string driver array blocks N and N+1, each of the array blocks including an A side transistors and B side transistors that are horizontally aligned in corresponding array block. In addition, each of the plurality of grounding regions 602 is disposed between neighboring parallelly aligned active regions 202. In particular, each of the plurality of grounding regions 602 passes through the corresponding STI region 204 along the width direction of the string driver array blocks and is surrounded by the TSI 206. In this example, the plurality of grounding regions 602 can be made of silicon that is heavily doped by P type dopant materials such as Boron and/or Gallium in a dose level close to or higher than 1×10²⁰ ions·cm⁻². Moreover, each of the plurality of grounding regions 602 may include a wiring contact 606. In each of the string driver array blocks, the wiring contact 606 of each of the plurality of grounding regions 602 can be interconnected through the wiring connection 604. As shown in FIG. 6, the wiring connection 604 can be routed within each string driver array block to interconnect the grounding regions disposed therein. Each of the wiring connections 604 for the string driver array blocks may include a contact (not shown) that transmits a biasing voltage to the body/well of parallelly aligned neighboring string driver devices in corresponding string driver array block so as to prevent the transistor body effect. In this example, the string driver transistors disposed in a same string driver array block can share a common well. As a result, by adjusting the biasing voltage transferred to corresponding wiring connection 604, the body/well of the string driver transistors in each one of the string driver array blocks can be biased separately.

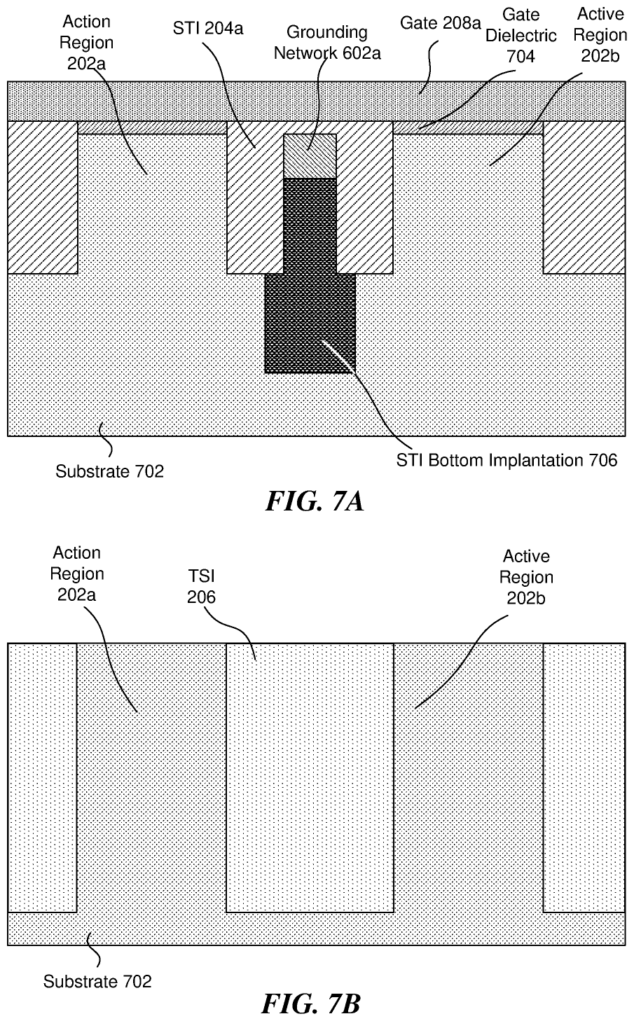

FIGS. 7A and 7B depict cross-sectional views of string drivers along the E-E′ plane and F-F′ plane shown in FIG. 6, respectively. In particular, the E-E′ plane is along the length direction of the gate 208a and passes through the gate 208a, the STI 204a, the active regions 202a and 202b, and the grounding region 602a. The F-F′ plane is parallel to the E-E′ plane, passing through the TSI 206 and the active regions 202a and 202b. As shown in FIG. 5A, the channels of the active regions 202a and 202b are parallelly aligned on a substrate 702. The gate 208a is disposed above the channels of the active regions 202a and 202b and transfer a shared gate voltage to the corresponding string driver transistors. In this example and for configuration of planar MOSFET string driver device, a gate dielectric layer 704 may be disposed above the top surface of the channel region of the active regions 202a and 202b, and underneath the shared gate 208a. Here, the gate dielectric layer 704 can be made of dielectric material with a high dielectric constant (e.g., SiO₂, ZrO₂, and/or HfO₂).

As described, the channels of neighboring string driver devices, i.e., the channels of the active regions 202a and 202b, can be isolated by the STI 204a. In addition, the grounding region 402a can be embedded in the STI 204a and disposed above a protruded STI bottom implantation region 706. The protruded STI bottom implantation region 706 can be similar to the protruded STI bottom implantation region 506 described in FIG. 5A. In this example, a top surface and sidewall surfaces of the grounding region 602a can be in a direct contact to the STI 204a. In addition, the grounding region 602a is connected, through the STI bottom implantation region 706, to the body of adjacent string driver transistors. This configuration enables a low resistance path for transferring the biasing voltage to the body of parallel aligned neighboring string driver devices to prevent transistor body effect. In this example, the top surface of the grounding region 602a is isolated from the gate 208a, i.e., having a gap filled by STI 204a therebetween. In this example, the grounding region 602a may be in a square shape from the cross-sectional view. It may have a width close to 0.15 μm and a depth ranging from 0.1 μm to 0.5 μm. Moreover, a distance from the grounding region 602a sidewall to sidewall of adjacent active region 202 can be close to 0.175 μm.

FIG. 7B shows a cross-section view of the string driver device along the F-F′ plane, which passes the drain regions of parallel aligned string driver FET transistors. As shown, the neighboring active regions 202a and 202b are isolated by TSI 206. There are no grounding regions included in this view because the plurality of grounding regions 602 are discontinuous close to the drain regions, e.g., only exist close to the parallelly aligned channel regions of neighboring string driver transistors, as shown in FIG. 6.

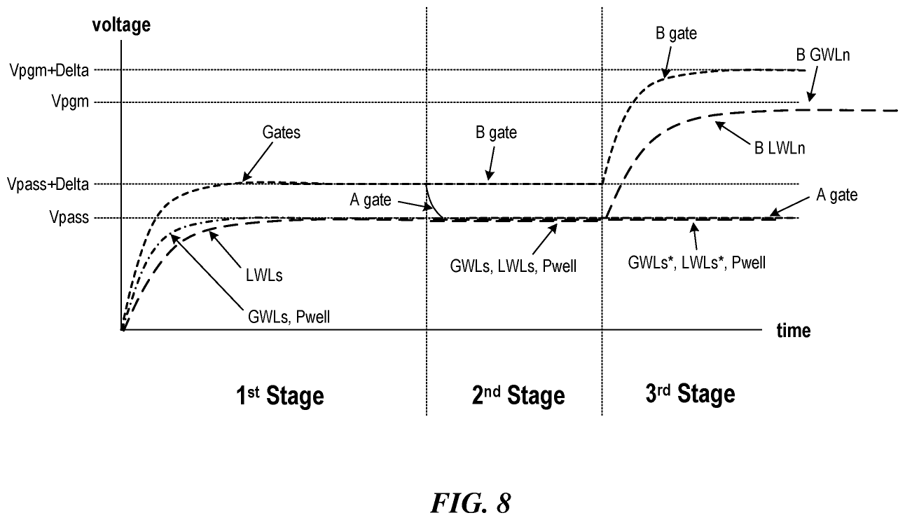

FIG. 8 illustrates program voltage traces of the A side and B side string driver devices in the string driver array blocks 600 in an overdrive operation mode according to embodiments of the present technology. In particular, the program voltage traces demonstrates an operation of the string driver transistors only in the string driver array block N. All other string driver array blocks such as the array block N+1 can be idle, e.g., setting its word line voltage and LWL voltage close to 0V, during programming the string driver devices of array block N. Further, the string driver transistors in each of the A side and B side array block are four terminal device receiving control voltages from the gate (e.g., gate 208a), the source (e.g., the LWL contact 210 for A side transistor), the drain (e.g., shared GWL contact 212 for both A side and B side transistors), and the body (e.g., the P well/body through the wiring contact 606 and corresponding the wiring connection), respectively.

In this example, the A side and B side string driver transistors in array block N can be operated in a first operation mode, having an overdrive A side gate voltage for a faster ramp to Vpass. Specifically, this first operation mode includes three stages as shown in FIG. 8. In the first stage, the gate voltage for A side and B side transistors are set to a level of Vpass+Delta. Switches that are connected to the shared drain and shared well/body are also turned on, so as to ramp the voltages of GWL contacts 212 and wiring contacts 606 to Vpass. Meanwhile, the voltage for source regions of A side and B side string driver transistors can be set, through the LWL contacts 210, to Vpass as well. In this first stage, the voltages for four terminals of the string driver devices on the A side and B side of array block N can be ramped up from 0V to corresponding target steady state voltages. In particular, the upstream voltage curves for the source regions (e.g., LWL contact voltage) may lag to that of the shared drain voltage and well/body voltage (e.g., GWL contact voltage and Pwell voltage) due to a higher resistance, which might be further minimized by optimizing the design of the string drive devices. In the intermediate second stage, the gate voltage for A side string driver transistors can drop to Vpass and the gate voltage of B side string driver transistors remain at the Vpass+Delta level. The voltages for source, drain, and well/body of A side and B side transistors are also remains at Vpass. In the third stage, the B side string driver transistors can be programmed, i.e., ramping up the gate voltage of B side string driver transistors to a level of Vpgm+Delta and the source and drain regions (e.g., the LWL contact voltage and GWL contact voltage) to a level of Vpgm. In this stage, the voltages for A side string driver transistor terminals including the corresponding source regions (e.g., LWL contact voltage), drain regions (e.g., GWL contact voltage), and well/body regions (e.g., wiring contact voltage) are all maintained at the Vpass level.

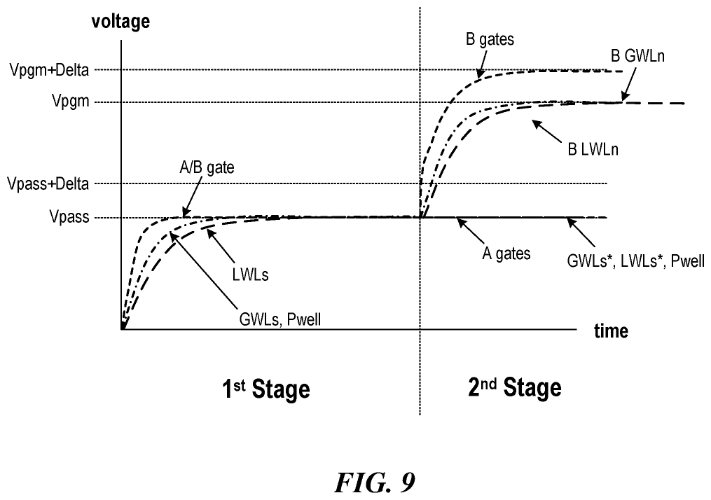

Turning to FIG. 9 which illustrates program voltage traces of the A side and B side string driver devices in the string driver array blocks 600 in another operation mode according to embodiments of the present technology. In this operation mode, the gate voltage of A side string driver devices are not overdriven during its voltage ramping up to the level of Vpass. Instead, it relies on the well/body voltage to supply charge the LWL contacts 210. Moreover, this operation mode for string driver devices in array blocks 600 only includes two stages, without having the intermediate stage. In the first stage of this operation mode, the gate voltage for A side and B side transistors are set to a level of Vpass. Switches that are connected to the shared drain and shared well/body are also turned on to ramp the voltages of GWL contacts 212 and wiring contacts 606 to Vpass. Meanwhile, the voltage for source regions of A side and B side string driver transistors can be set, through the LWL contacts 210, to Vpass as well. In this stage, the voltages for four terminals of the string driver devices on the A side and B side of array block N can be ramped up from 0V to corresponding target steady state voltages. In this example, there may be a time lag between the upstream voltage curves for the source regions (e.g., LWL contact voltage) and that for the shared drain voltage and well/body voltage (e.g., GWL contact voltage and Pwell voltage) due to a higher resistance, which might be further minimized by optimizing the design of the string drive devices. In the second stage, the B side string driver transistors can be programmed, i.e., ramping up its gate voltage to the level of Vpgm+Delta and the source and drain regions (e.g., the LWL contact voltage and GWL contact voltage) to a level of Vpgm, by turning on corresponding Vpgm switches and turning off corresponding Vpass switches connected to the B side string driver devices. In particular, the upstream trace of GWL voltage may be followed by the upstream trace of LWL voltage, both eventually entering into a steady state Vpgm. In this stage, the voltages for A side string driver transistor terminals including the corresponding source regions (e.g., LWL contact voltage), drain regions (e.g., GWL contact voltage), and well/body regions (e.g., wiring contact voltage) are all maintained at the Vpass level.

In the present technology, the string driver devices may show a faster ramp to the Vpass voltage, as shown in the FIG. 9, due to the plurality of grounding regions 602 connected to the body/well regions of corresponding string driver transistors. Furthermore, the faster ramp voltages may contribute to a lower overall program time (Tprog) of the string driver devices. In addition, the grounding network or grounding regions introduced in the present technology can effectively inhibit body effects on the string driver transistors during the voltage ramp up further to Vprog. This configuration enables a less delta voltage to stimulate the drive current in the string driver devices. Alternatively, it can help achieve a higher driver current for a given delta voltage value.

The STI regions and grounding network/regions included in the string driver devices of the present technology can reduce a maximum string driver die voltage through a better oxide reliability and/or thinner oxide isolations in the string driver devices, which can be also helpful to form smaller pumps or smaller HV transistors therein. Moreover, the reduced well/body effect in string driver transistors of the present technology can help reduce the memory array word line rise time, e.g., through the reduced Tprog. As described earlier on FIG. 6, each of the string driver array blocks can be controlled specifically through corresponding grounding regions 602. It is therefore possible to reduce a capacitance of the string driver array blocks by only biasing/applying negative voltages to interested/specific array blocks.

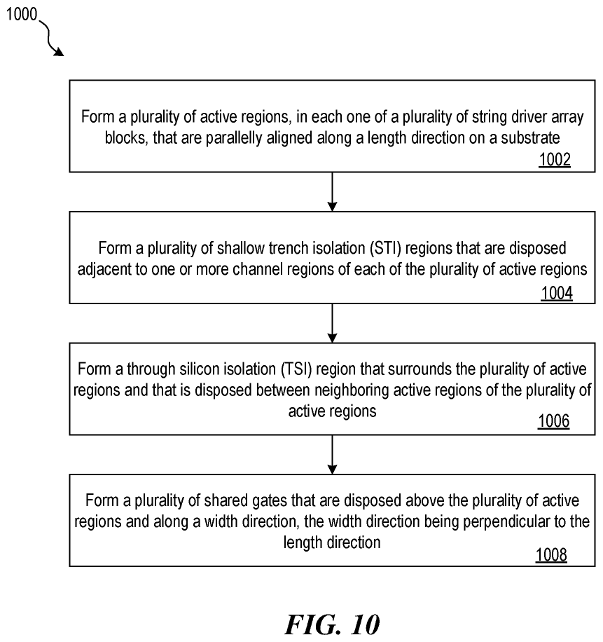

FIG. 10 is a flow chart illustrating a method 1000 of processing the string driver array blocks for F2B POC WOW bonding in semiconductor device assembly according to embodiments of the present technology. For example, the method 1000 includes forming a plurality of active regions, in each one of a plurality of string driver array blocks, that are parallelly aligned along a length direction on a substrate, at 1002. For example, the plurality of action regions 202 can be fabricated on the substrate 302 along the length direction of the string driver array blocks 200. As shown in FIG. 2, each of the plurality of active regions 202 are parallelly aligned within the corresponding string driver array block.

The method 1000 also includes forming a plurality of STI regions that are disposed adjacent to one or more channel regions of each of the plurality of active regions, at 1004. For example, the plurality of STI regions 204 can be fabricated in the string driver array blocks 200. In particular, each of the plurality of STI regions 204 can be disposed close to corresponding channel regions of the plurality of active regions 202. As shown in FIG. 2, the STI region 204a can be formed close to one of the channel regions of the active region 202a.

In addition, the method 1000 includes forming a through silicon isolation (TSI) region that surrounds the plurality of active regions on the substrate and that is disposed between neighboring active regions of the plurality of active regions, at 1006. For example, the TSI 206 can be formed above the substrate 302 and to surround the plurality of active regions 202 and the plurality of STI regions 204 for electrical isolation.

Lastly, the method 1000 includes forming a plurality of shared gates that are disposed above the plurality of active regions and along a width direction, the width direction being perpendicular to the length direction, at 1008. For example, the plurality of gates 208 can be formed above the plurality of active regions 202 of the string driver array blocks 200. Specifically, each of the plurality of gates 208 can be aligned along the width direction of the string driver array block. Moreover, the parallelly aligned string driver transistors in each of the string driver array blocks can share a same gate voltage through corresponding one of the plurality of gates 208, as shown in FIG. 2.

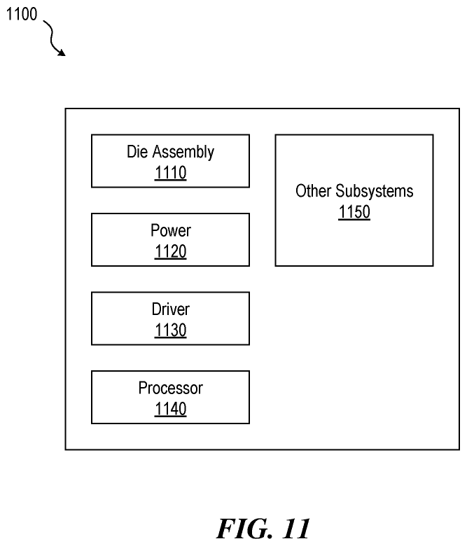

Any one of the semiconductor structures described above with reference to FIGS. 1-7B can be incorporated into any of a myriad of larger and/or more complex systems, a representative example of which is system 1100 shown schematically in FIG. 11. The system 1100 can include a semiconductor device 1110, a power source 1120, a driver 1130, a processor 1140, and/or other subsystems or components 1150. The semiconductor device 1110 can include features generally similar to those of the semiconductor devices described above and can therefore include string drivers with through silicon isolation described in the present technology. The resulting system 1100 can perform any of a wide variety of functions, such as memory storage, data processing, and/or other suitable functions. Accordingly, representative systems 1100 can include, without limitation, hand-held devices (e.g., mobile phones, tablets, digital readers, and digital audio players), computers, and appliances. Components of the system 1100 may be housed in a single unit or distributed over multiple, interconnected units (e.g., through a communications network). The components of the system 1100 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A string driver device, comprising:
a substrate; and
a plurality of string driver array blocks that are disposed above the substrate, each of the plurality of string driver array blocks comprising:
a plurality of active regions that are parallelly aligned along a length direction,
a plurality of shared gates that are disposed above the plurality of active regions and along a width direction, the width direction being perpendicular to the length direction,
a through silicon isolation (TSI) region that surrounds the plurality of active regions on the substrate and that is disposed between neighboring active regions of the plurality of active regions,
a plurality of shallow trench isolation (STI) regions that are disposed adjacent to one or more channel regions of each of the plurality of active regions and below the plurality of shared gates respectively, and
a plurality of through silicon contacts each being disposed in the TSI region and close to both ends of each of the plurality of active regions,
wherein each of the plurality of STI regions is connected to the TSI region along the length direction.

2. The string driver device of claim 1, further comprising:
a plurality of global word line contacts that each is disposed on corresponding one of the plurality of active regions; and
a plurality of local word line contacts that each is disposed on one end of the corresponding one of the plurality of active regions,
wherein the plurality of through silicon contacts are connected to the plurality of local word line contacts, respectively.

3. The string driver device of claim 1, further comprising a grounding network that is connected to the substrate of the string driver device, wherein the grounding network is disposed across the plurality of string driver array blocks.

4. The string driver device of claim 3, wherein the grounding network comprises:
a plurality of horizontal components that are aligned along the length direction and cross the plurality of string driver array blocks, each of the plurality of horizontal components being disposed between the neighboring active regions of the plurality of active regions, and
a plurality of vertical components that are aligned along the width direction, each of the plurality of vertical components being disposed between neighboring string driver array blocks.

5. The string driver device of claim 4, wherein each one of the plurality of horizontal components of the grounding network is embedded, between parallelly aligned neighboring channel regions of the plurality of active regions, in corresponding one of the plurality of STI regions.

6. The string driver device of claim 4, wherein each one of the plurality of vertical components of the grounding network is embedded, between neighboring string driver array blocks, in the TSI region.

7. The string driver device of claim 3, further comprising a plurality of STI bottom implant regions, each of the plurality of STI bottom implant regions being disposed underneath and connected to the grounding network.

8. The string driver device of claim 7, wherein the grounding network comprises heavily doped semiconductor materials, and wherein the plurality of STI bottom implant regions comprise lightly doped semiconductor materials.

9. The string driver device of claim 3, further comprising one or more body contacts that are disposed above the grounding network, wherein the one or more body contacts are configured to transmit a biasing voltage to the grounding network.

10. The string driver device of claim 1, further comprising, in each one of the plurality of string driver array blocks, a plurality of grounding regions that are parallelly aligned along the length direction, each one of the plurality of grounding regions being disposed between the neighboring active regions of the plurality of active regions.

11. The string driver device of claim 10, wherein each one of the plurality of grounding regions is embedded, between parallelly aligned neighboring channel regions of the plurality of active regions, in corresponding one of the plurality of STI regions.

12. The string driver device of claim 11, further comprising, in each one of the plurality of string driver array blocks, a plurality of body contacts each being disposed on corresponding one of the plurality of grounding regions, wherein the plurality of body contacts of each one of the plurality of string driver array blocks are interconnected by a wiring connection that is configured to transmit a biasing voltage to a body of the corresponding one of the plurality of string driver array blocks.

13. A semiconductor device assembly, comprising:
a complementary metal-oxide-semiconductor (CMOS) device having a plurality of string driver array blocks that are disposed above a substrate of the CMOS device, each of the plurality of string driver array blocks comprising:
a plurality of active regions that are parallelly aligned along a length direction,
a plurality of shared gates that are disposed above the plurality of active regions and along a width direction, the width direction being perpendicular to the length direction,
a through silicon isolation (TSI) region that surrounds the plurality of active regions on the substrate and that is disposed between neighboring active regions of the plurality of active regions, and
a plurality of shallow trench isolation (STI) regions that are disposed adjacent to one or more channel regions of each of the plurality of active regions and below the plurality of shared gates respectively; and
a memory array device having one or more memory arrays,
wherein a backside surface of the CMOS device is bonded to the frontside surface of the memory array device by dielectric-dielectric fusion bonds.

14. The semiconductor device assembly of claim 13, further comprising a plurality of through silicon contacts in the CMOS device, each of the plurality of through silicon contacts being disposed in the TSI region and close to both ends of each of the plurality of active regions, wherein each of the plurality of STI regions is connected to the TSI region along the length direction.

15. The semiconductor device assembly of claim 14, wherein the CMOS device further comprises a grounding network that is connected to the substrate of the CMOS device, and wherein the grounding network is disposed across the plurality of string driver array blocks.

16. The semiconductor device assembly of claim 15, wherein the grounding network comprises:
a plurality of horizontal components that are aligned along the length direction and cross the plurality of string driver array blocks, each of the plurality of horizontal components being disposed between the neighboring active regions of the plurality of active regions, and
a plurality of vertical components that are aligned along the width direction, each of the plurality of vertical components being disposed between neighboring string driver array blocks.

17. The semiconductor device assembly of claim 14, wherein the CMOS device further comprises, in each one of the plurality of string driver array blocks, a plurality of grounding regions that are parallelly aligned along the length direction, each one of the plurality of grounding regions being disposed between the neighboring active regions of the plurality of active regions.

18. A method of forming a string driver device, comprising:
forming a plurality of active regions, in each one of a plurality of string driver array blocks, that are parallelly aligned along a length direction on a substrate;
forming a plurality of shallow trench isolation (STI) regions that are disposed adjacent to one or more channel regions of each of the plurality of active regions;
forming a through silicon isolation (TSI) region that surrounds the plurality of active regions on the substrate and that is disposed between neighboring active regions of the plurality of active regions; and
forming a plurality of shared gates that are disposed above the plurality of active regions and along a width direction, the width direction being perpendicular to the length direction.

19. The method of forming the string driver device of claim 18, further comprising forming a grounding network that is connected to the substrate, wherein the grounding network is disposed across the plurality of string driver array blocks on the substrate, and wherein the grounding network comprises:
a plurality of horizontal components that are aligned along the length direction and cross the plurality of string driver array blocks, each of the plurality of horizontal components being disposed between the neighboring active regions of the plurality of active regions, and
a plurality of vertical components that are aligned along the width direction, each of the plurality of vertical components being disposed between neighboring string driver array blocks.

20. The method of forming the string driver device of claim 18, further comprising forming, in each one of the plurality of string driver array blocks, a plurality of grounding regions that are parallelly aligned along the length direction, each one of the plurality of grounding regions being disposed between the neighboring active regions of the plurality of active regions.
